(19) United States
(12) Patent Application Publication
(10) Pub. No.: US 2024/0195372 A1
(43) Pub. Date: Jun. 13, 2024

(54) SEMICONDUCTOR INTEGRATED CIRCUIT AND SEMICONDUCTOR MEMORY DEVICE

(71) Applicant: Kioxia Corporation, Tokyo (JP)

(72) Inventors: Yutaka SHIMIZU, Yokohama (JP); Yasuhiro HIRASHIMA, Kawasaki (JP); Isao FUJISAWA, Yokohama (JP); Michael BURGHART, Kamakura (JP); Yuanlun ZHANG, Kawasaki (JP)

(73) Assignee: Kioxia Corporation, Tokyo (JP)

(21) Appl. No.: 18/489,140

(22) Filed: Oct. 18, 2023

(30) Foreign Application Priority Data
Oct. 19, 2022 (JP) 2022-167716

(51) Int. Cl. H03F 3/45; H10B 41/30; H10B 43/30

(52) U.S. Cl. CPC H03F 3/45659; H10B 41/30; H10B 43/30; H03F 2203/45091

(57) ABSTRACT

An amplifier of an input circuit includes: a first PMOS transistor having a gate connected to a first node, a source connected to a second node, and a drain connected to a third node; a second PMOS transistor having a gate connected to a fourth node that inputs a reference signal, a source connected to the second node, and a drain connected to a fifth node; a current source connected between a power supply voltage and the second node; a load circuit connected between the third node and a ground voltage; a first NMOS transistor having a gate connected to the first node, a drain connected to the power supply voltage, and a source connected to the fifth node; and a second NMOS transistor having a gate connected to the fourth node, a drain connected to the power supply voltage, and a source connected to the third node.

### CROSS-REFERENCE TO RELATED APPLICATIONS

This application is based upon and claims the benefit of Japanese Patent Application No. 2022-167716, filed on Oct. 19, 2022, the entire contents of which are incorporated herein by reference.

### BACKGROUND

### Field

Embodiments described herein relate generally to a semiconductor integrated circuit and a semiconductor memory device.

### Description of the Related Art

A semiconductor memory device that includes a memory cell array including a plurality of memory cells and an input circuit that is connected to this memory cell array and inputs user data according to an input of a command set including command data and address data is known.

### BRIEF DESCRIPTION OF THE DRAWINGS

FIG. 1 is a schematic block diagram illustrating a configuration of a memory system 10;

FIG. 2 is a schematic side view illustrating an exemplary configuration of the memory system 10;

FIG. 3 is a schematic plan view illustrating an exemplary configuration of the memory system 10;

FIG. 4 is a schematic block diagram illustrating a configuration of a memory die MD;

FIG. 5 is a schematic circuit diagram illustrating a configuration of a part of the memory die MD;

FIG. 6 is a schematic perspective view illustrating a configuration of a part of the memory die MD;

FIG. 7 is a schematic circuit diagram illustrating a configuration of a part of the memory die MD;

FIG. 8 is a schematic block diagram illustrating a configuration of a part of an input/output control circuit I/O;

FIG. 9 is a schematic block diagram illustrating configurations of input circuits 210, 220 and an input buffer circuit 230;

FIG. 10A is a schematic circuit diagram illustrating a configuration of a comparator 211 according to a first embodiment;

FIG. 10B is a schematic circuit diagram illustrating a configuration of a comparator 211G according to a comparative example;

FIG. 11 is a timing chart illustrating an input example of a data signal in a write operation;

FIG. 12A, FIG. 12B, FIG. 12C and FIG. 12D are waveform diagrams illustrating an operation of the comparator 211;

FIG. 13A, FIG. 13B, and FIG. 13C are waveform diagrams illustrating an operation of the comparator 211;

FIG. 14A, FIG. 14B, FIG. 14C, and FIG. 14D are waveform diagrams illustrating an operation of the comparator 211;

FIG. 15 is a schematic circuit diagram illustrating a configuration of a comparator 211A according to a second embodiment;

FIG. 16 is a schematic circuit diagram illustrating a configuration of a comparator 211B according to a third embodiment;

FIG. 17 is a schematic circuit diagram illustrating a configuration of a comparator 211C according to a fourth embodiment;

FIG. 18 is a schematic circuit diagram illustrating a configuration of a first amplifier 300 according to a fifth embodiment;

FIG. 19 is a schematic circuit diagram illustrating a configuration of a comparator 211D according to a sixth embodiment; and

FIG. 20 is a schematic circuit diagram illustrating a configuration of a comparator 211E according to a seventh embodiment.

### DETAILED DESCRIPTION

A semiconductor integrated circuit according to one embodiment comprises an input circuit that includes an amplifier. The amplifier includes: a current source electrically connected to a power supply voltage; a first PMOS transistor having a gate electrically connected to a first node that inputs a data signal, a source electrically connected to the current source, and a drain electrically connected to a second node; a second PMOS transistor having a gate electrically connected to a third node that inputs a reference signal, a source electrically connected to the current source, and a drain electrically connected to a fourth node; a load circuit electrically connected between the second node and a ground voltage and between the fourth node and the ground voltage; a first NMOS transistor having a gate electrically connected to the first node, a drain electrically connected to the power supply voltage, and a source electrically connected to the fourth node; a second NMOS transistor having a gate electrically connected to the third node, a drain electrically connected to the power supply voltage, and a source electrically connected to the second node; a first current restriction circuit electrically connected between the drain of the first NMOS transistor and the power supply voltage; and a second current restriction circuit electrically connected between the drain of the second NMOS transistor and the power supply voltage.

Next, a semiconductor integrated circuit and a semiconductor memory device according to embodiments are described in detail with reference to the drawings. The following embodiments are only examples, and not described for the purpose of limiting the present invention.

In this specification, when referring to a “semiconductor memory device”, it may mean a memory die (memory chip) and may mean a memory system including a controller die, such as a memory card and an SSD. Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is connected between” the second configuration and a third configuration, it may mean that the first configuration, the second configuration, and the third configuration are connected in series and the second configuration is connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like is turned ON.

### First Embodiment

### [Memory System 10]

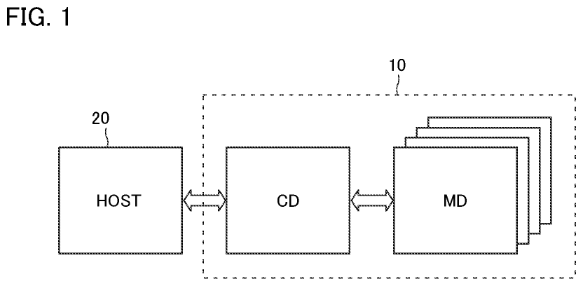

FIG. 1 is a schematic block diagram illustrating a configuration of the memory system 10.

The memory system 10, for example, reads, writes, and erases user data according to a signal transmitted from a host computer 20. The memory system 10 is, for example, any system that can store user data including a memory card and an SSD. The memory system 10 includes a plurality of memory dies MD that store the user data and a controller die CD connected to these plurality of memory dies MD and the host computer 20. The controller die CD includes, for example, a processor, a RAM, and the like, and performs conversion between a logical address and a physical address, bit error detection/correction, a garbage collection (compaction), a wear leveling, and the like.

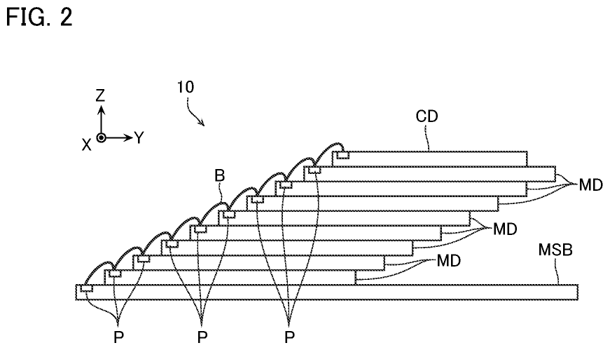

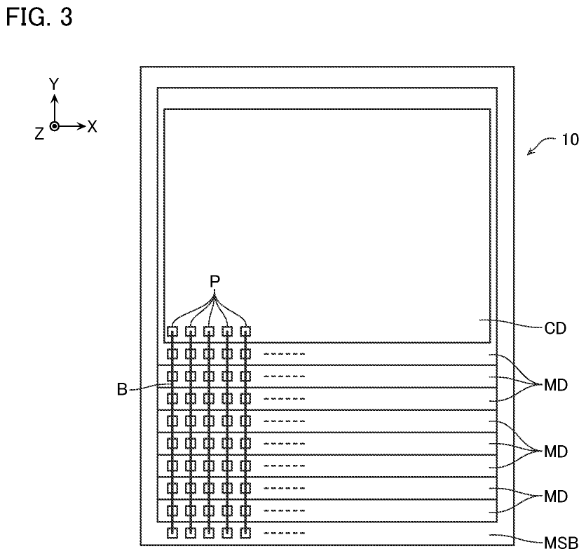

FIG. 2 is a schematic side view illustrating an exemplary configuration of the memory system 10 according to the embodiment. FIG. 3 is a schematic plan view illustrating the exemplary configuration. For convenience of description, FIG. 2 and FIG. 3 omit a part of the configuration.

As illustrated in FIG. 2, the memory system 10 according to the embodiment includes a mounting substrate MSB, the plurality of memory dies MD stacked on the mounting substrate MSB, and the controller die CD stacked on the memory dies MD. On an upper surface of the mounting substrate MSB, a pad electrode P is disposed in a region at an end portion in a Y-direction, and a part of the other region is bonded to a lower surface of the memory die MD via an adhesive and the like. On an upper surface of the memory die MD, the pad electrode P is disposed in a region at an end portion in the Y-direction, and the other region is bonded to a lower surface of another memory die MD or the controller die CD via the adhesive and the like. On an upper surface of the controller die CD, the pad electrode P is disposed in a region at an end portion in the Y-direction.

As illustrated in FIG. 3, the mounting substrate MSB, the plurality of memory dies MD, and the controller die CD each include a plurality of the pad electrodes P arranged in an X-direction. The plurality of pad electrodes P disposed on each of the mounting substrate MSB, the plurality of memory dies MD, and the controller die CD are mutually connected via bonding wires B.

Note that the configuration illustrated in FIG. 2 and FIG. 3 is merely an example, and specific configurations are appropriately adjustable. For example, in the example illustrated in FIG. 2 and FIG. 3, the controller die CD is stacked on the plurality of memory dies MD, and these configurations are connected with the bonding wires B. In such a configuration, the plurality of memory dies MD and the controller die CD are included in one package. However, the controller die CD may be included in a package different from the memory die MD. Additionally, the plurality of memory dies MD and the controller die CD may be connected to one another via through electrodes or the like, not the bonding wires B.

### [Configuration of Memory Die MD]

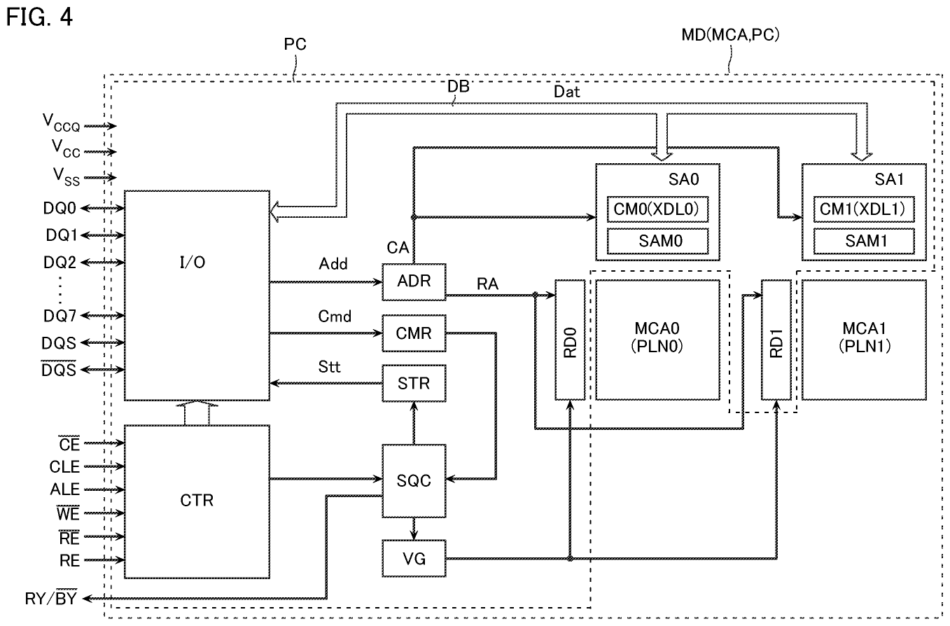

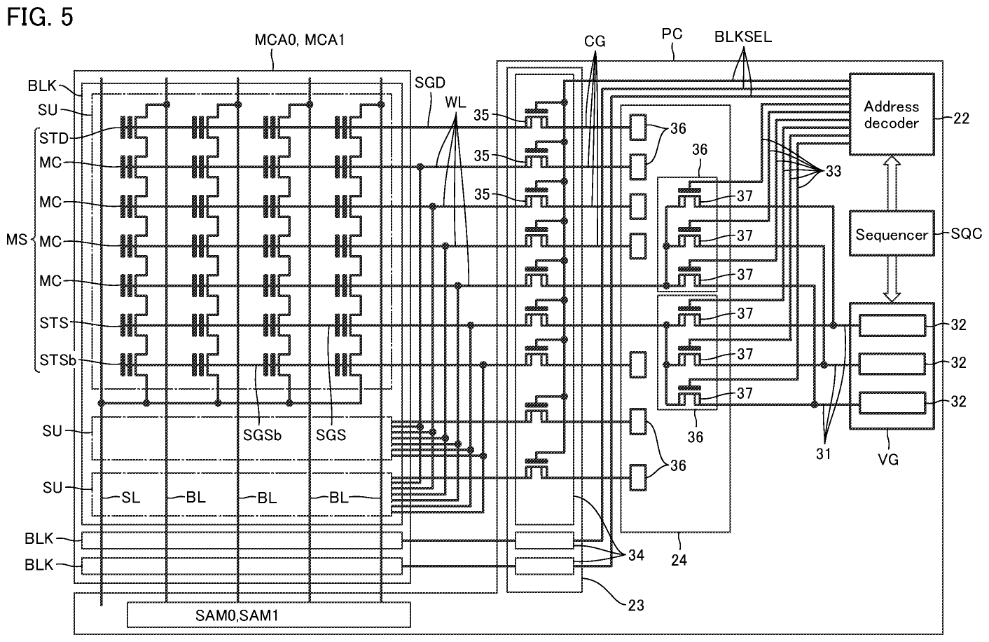

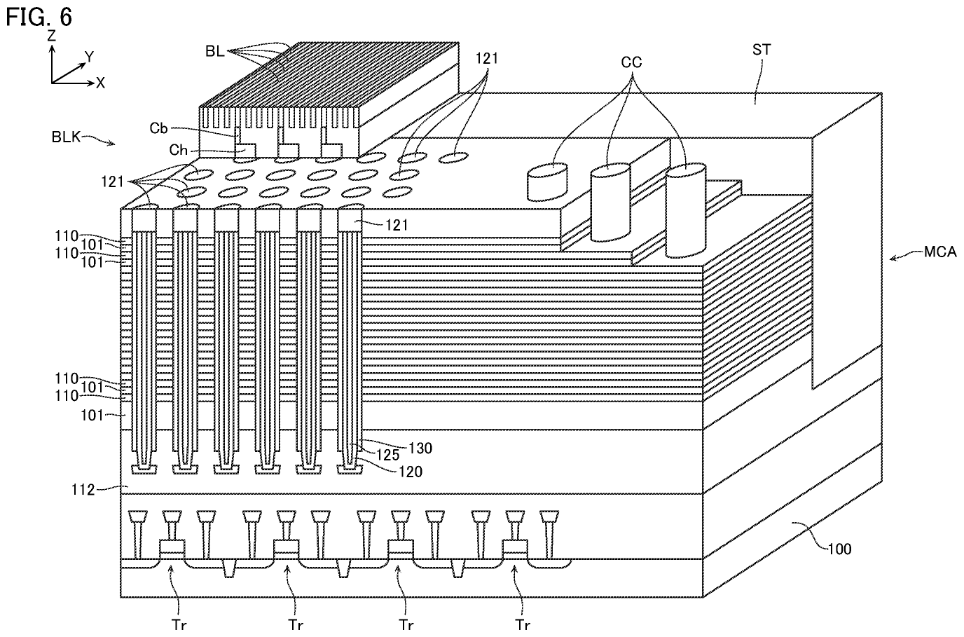

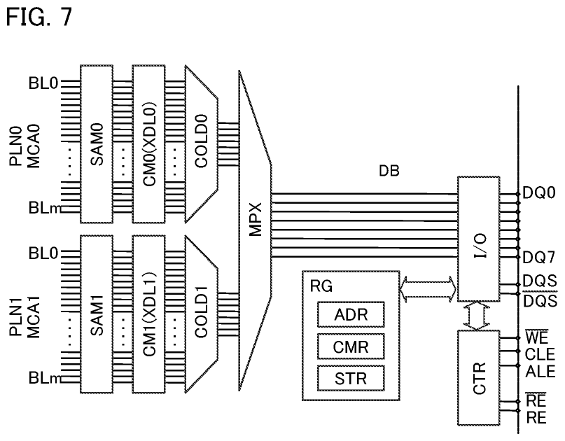

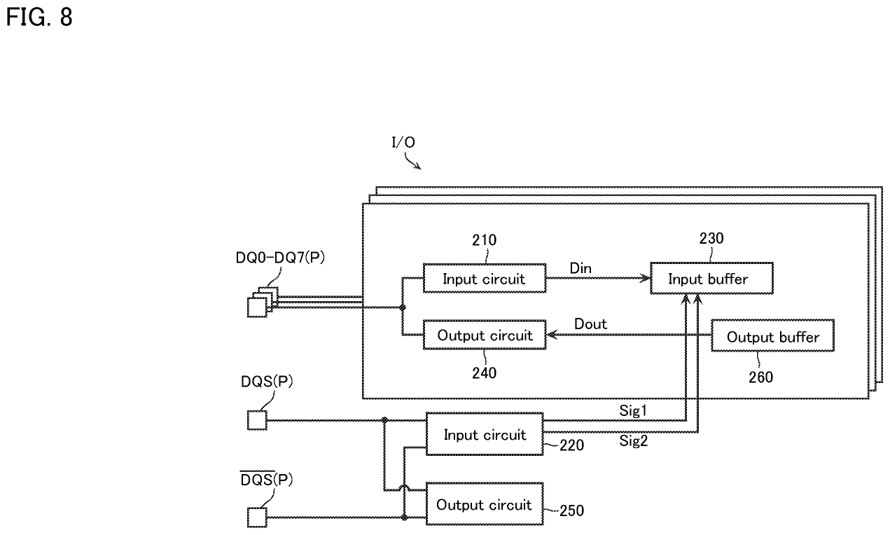

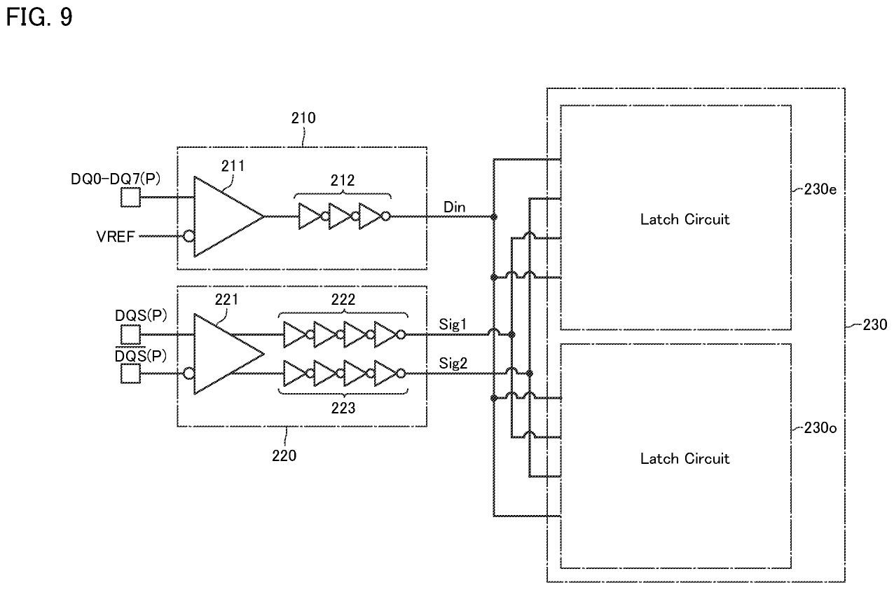

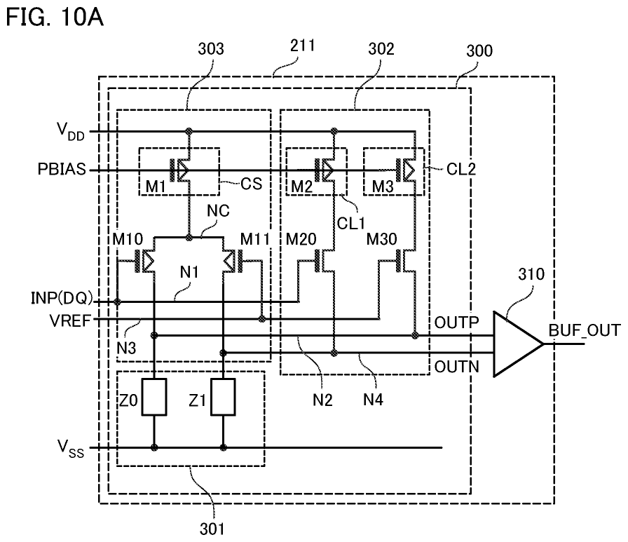

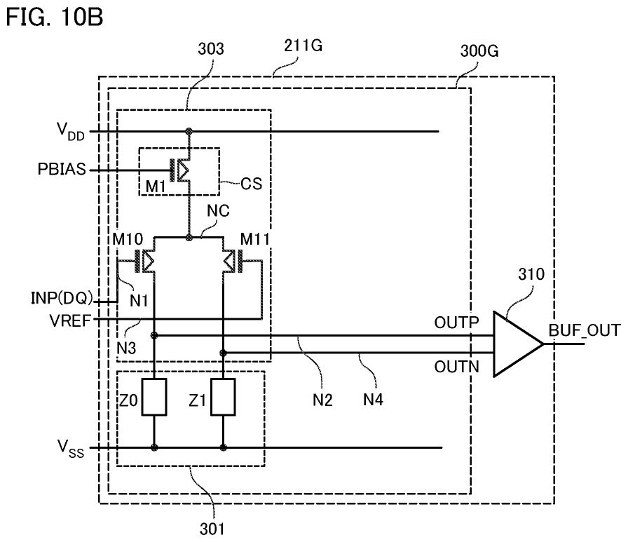

FIG. 4 is a schematic block diagram illustrating a configuration of the memory die MD according to the first embodiment. FIG. 5 is a schematic circuit diagram illustrating a configuration of a part of the memory die MD. FIG. 6 is a schematic perspective view illustrating a configuration of a part of the memory die MD. FIG. 7 is a schematic circuit diagram illustrating a configuration of a part of the memory die MD. FIG. 8 is a schematic block diagram illustrating a configuration of a part of an input/output control circuit I/O. FIG. 9 is a schematic block diagram illustrating configurations of input circuits 210, 220 and an input buffer circuit 230. FIG. 10A is a schematic circuit diagram illustrating a configuration of a comparator 211 according to the first embodiment. FIG. 10B is a schematic circuit diagram illustrating a configuration of a comparator 211G according to a comparative example. Note that a first amplifier 300G of the comparator 211G in FIG. 10B is a circuit that excludes a source follower circuit 302 from the first amplifier 300 of the comparator 211 in FIG. 10A.

FIG. 4 illustrates a plurality of control terminals and the like. These plurality of control terminals are represented as control terminals corresponding to a high active signal (positive logic signal) in some cases, represented as control terminals corresponding to a low active signal (negative logic signal) in some cases, and represented as control terminals corresponding to both the high active signal and the low active signal in some cases. In FIG. 4, a reference sign of the control terminal corresponding to the low active signal includes an over line (overbar). In this specification, a reference sign of the control terminal corresponding to the low active signal includes a slash (“/”). The description of FIG. 4 is an example, and specific aspects are appropriately adjustable. For example, a part of or all of the high active signals can be changed to the low active signals, or a part of or all of the low active signals can be changed to the high active signals.

Next to the plurality of control terminals illustrated in FIG. 4, an arrow indicating an input/output direction is illustrated. In FIG. 4, the control terminals provided with an arrow pointing from left to right are usable for an input of data or other signals from the controller die CD to the memory die MD. In FIG. 4, the control terminals provided with an arrow pointing from right to left are usable for an output of data or other signals from the memory die MD to the controller die CD. In FIG. 4, the control terminals provided with an arrow pointing to both left and right directions are usable in both directions for an input of data or other signals from the controller die CD to the memory die MD and for an output of data or other signals from the memory die MD to the controller die CD.

FIG. 4 also illustrates a plurality of power supply voltage input terminals and the like arranged with the plurality of control terminals and the like. To the plurality of power supply voltage input terminals and the like, for example, a power supply voltage V_{CC}, an input/output power supply voltage V_{CCQ}, and a ground voltage V_{SS} (FIG. 4) are applied.

As illustrated in FIG. 4, the memory die MD includes memory cell arrays MCA0, MCA1 storing the user data, and a peripheral circuit PC connected to the memory cell arrays MCA0, MCA1. In the following description, the memory cell arrays MCA0, MCA1 are referred to as a memory cell array MCA in some cases. The memory cell arrays MCA0, MCA1 are referred to as planes PLN0, PLN1 in some cases.

In this specification, a part of or all of the peripheral circuit PC is referred to as a “semiconductor integrated circuit” in some cases. The semiconductor integrated circuit at least includes the input/output control circuit I/O (FIG. 4, FIG. 8).

### [Configuration of Memory Cell Array MCA]

As illustrated in FIG. 5, the memory cell array MCA includes a plurality of memory blocks BLK. These plurality of memory blocks BLK each include a plurality of string units SU. These plurality of string units SU each include a plurality of memory strings MS. These plurality of memory strings MS have one ends each connected to the peripheral circuit PC via bit lines BL. Furthermore, these plurality of memory strings MS have the other ends each connected to the peripheral circuit PC via a common source line SL.

The memory string MS includes a drain-side select transistor STD, a plurality of memory cells MC (memory cell transistors), a source-side select transistor STS, and a source-side select transistor STSb, which are connected in series between the bit line BL and the source line SL. Hereinafter, the drain-side select transistor STD, the source-side select transistor STS, and the source-side select transistor STSb may be simply referred to as select transistors (STD, STS, STSb).

The memory cell MC is a field-effect type transistor including a semiconductor layer, a gate insulating film, and a gate electrode. The semiconductor layer functions as a channel region. The gate insulating film includes an electric charge accumulating film. A threshold voltage of the memory cell MC changes according to an electric charge amount in the electric charge accumulating film. The memory cell MC stores one bit or a plurality of bits of user data. Word lines WL are connected to the respective gate electrodes of the plurality of memory cells MC corresponding to one memory string MS. These respective word lines WL are connected to all of the memory strings MS in one memory block BLK in common.

The select transistors (STD, STS, STSb) are field-effect type transistors each including a semiconductor layer, a gate insulating film, and a gate electrode. The semiconductor layer functions as a channel region. Select gate lines (SGD, SGS, SGSb) are connected to the respective gate electrodes of the select transistors (STD, STS, STSb). The drain-side select gate line SGD is disposed corresponding to the string unit SU and connected to all of the memory strings MS in one string unit SU in common. The source-side select gate line SGS is connected to all of the memory strings MS in the memory block BLK in common. The source-side select gate line SGSb is connected to all of the memory strings MS in the memory block BLK in common.

For example, as illustrated in FIG. 6, the memory cell array MCA is disposed above a semiconductor substrate 100. In the example of FIG. 6, a plurality of transistors Tr constituting the peripheral circuit PC are disposed between the semiconductor substrate 100 and the memory cell array MCA.

The memory cell array MCA includes the plurality of memory blocks BLK arranged in the Y-direction. Between two memory blocks BLK adjacent in the Y-direction, an inter-block insulating layer ST of silicon oxide (SiO₂) or the like is disposed.

For example, as illustrated in FIG. 6, the memory block BLK includes a plurality of conductive layers 110 arranged in a Z-direction, a plurality of semiconductor columns 120 extending in the Z-direction, and a respective plurality of gate insulating films 130 disposed between the plurality of conductive layers 110 and the plurality of semiconductor columns 120.

The conductive layer 110 is an approximately plate-shaped conductive layer extending in the X-direction. The conductive layer 110 may include a stacked film of a barrier conductive film, such as titanium nitride (TiN), and a metal film, such as tungsten (W), or the like. For example, the conductive layer 110 may contain polycrystalline silicon containing impurities, such as phosphorus (P) or boron (B), or the like. Between the plurality of conductive layers 110 arranged in the Z-direction, insulating layers 101 of silicon oxide (SiO₂) or the like are disposed.

Among the plurality of conductive layers 110, two or more conductive layers 110 positioned at the lowermost layer function as the source-side select gate lines SGS, SGSb (FIG. 5) and gate electrodes of the plurality of source-side select transistors STS, STSb connected to the source-side select gate lines SGS, SGSb. These plurality of conductive layers 110 are electrically independent in every memory block BLK.

A plurality of conductive layers 110 positioned above these conductive layers 110 function as the word lines WL (FIG. 5) and gate electrodes of the plurality of memory cells MC (FIG. 5) connected to the word lines WL. These plurality of conductive layers 110 are each electrically independent in every memory block BLK.

One or a plurality of conductive layers 110 positioned above these conductive layers 110 function as the drain-side select gate lines SGD and gate electrodes of the plurality of drain-side select transistors STD (FIG. 5) connected to the drain-side select gate lines SGD. These plurality of conductive layers 110 have widths in the Y-direction smaller than those of other conductive layers 110.

A semiconductor layer 112 is disposed below the conductive layer 110. For example, the semiconductor layer 112 may contain polycrystalline silicon containing impurities, such as phosphorus (P) or boron (B), or the like. Between the semiconductor layer 112 and the conductive layer 110, the insulating layer 101 of silicon oxide (SiO₂) or the like is disposed.

The semiconductor layer 112 functions as the source line SL (FIG. 5). The source line SL is, for example, disposed in common in all of the memory blocks BLK included in the memory cell array MCA.

For example, as illustrated in FIG. 6, the semiconductor columns 120 are arranged in the X-direction and the Y-direction in a predetermined pattern. The semiconductor columns 120 function as the channel regions of the plurality of memory cells MC and the select transistors (STD, STS, STSb) included in one memory string MS (FIG. 5). The semiconductor column 120 is, for example, a semiconductor layer of polycrystalline silicon (Si) or the like. For example, as illustrated in FIG. 6, the semiconductor column 120 has an approximately closed-bottomed cylindrical shape and includes an insulating layer 125 of silicon oxide or the like at its center part. Each of outer peripheral surfaces of the semiconductor columns 120 is surrounded by the conductive layers 110 and is opposed to the conductive layers 110.

In an upper end portion of the semiconductor column 120, an impurity region 121 containing N type impurities, such as phosphorus (P), is disposed. The impurity region 121 is connected to the bit line BL via a contact Ch and a contact Cb.

The gate insulating film 130 has an approximately closed-bottomed cylindrical shape that covers the outer peripheral surface of the semiconductor column 120. The gate insulating film 130 includes, for example, a tunnel insulating film, an electric charge accumulating film, and a block insulating film, which are stacked between the semiconductor column 120 and the conductive layers 110. The tunnel insulating film and the block insulating film are, for example, insulating films of silicon oxide (SiO₂) or the like. The electric charge accumulating film is, for example, a film of silicon nitride (Si₃N₄) or the like that can accumulate electric charges. The tunnel insulating film, the electric charge accumulating film, and the block insulating film have substantially cylindrical shapes and extend in the Z-direction along the outer peripheral surface of the semiconductor column 120 excluding a contact portion between the semiconductor column 120 and the semiconductor layer 112.

The gate insulating film 130 may, for example, include a floating gate of polycrystalline silicon containing N type or P type impurities or the like.

The plurality of conductive layers 110 have end portions in the X-direction where a plurality of contacts CC are disposed. The plurality of conductive layers 110 are connected to the peripheral circuit PC via these plurality of contacts CC. As illustrated in FIG. 6, these plurality of contacts CC extend in the Z-direction, and have lower ends connected to the conductive layers 110. The contacts CC may, for example, include a stacked film of a barrier conductive film of titanium nitride (TiN) or the like and a metal film of tungsten (W) or the like.

### [Configuration of Peripheral Circuit PC]

For example, as illustrated in FIG. 4, the peripheral circuit PC includes row decoders RD0, RD1 and sense amplifiers SA0, SA1. The peripheral circuit PC includes a voltage generation circuit VG and a sequencer SQC. The peripheral circuit PC includes the input/output control circuit I/O, a logic circuit CTR, an address register ADR, a command register CMR, and a status register STR. In the following description, the row decoders RD0, RD1 are referred to as a row decoder RD, and the sense amplifiers SA0, SAL are referred to as a sense amplifier SA in some cases. To describe differently, all parts other than the memory cell array MCA (connected to the respective memory cell arrays MCA0, MCA1) in the memory die MD function as the peripheral circuit PC.

### [Configuration of Row Decoder RD]

For example, as illustrated in FIG. 5, the row decoder RD (FIG. 4) includes an address decoder 22 decoding address data Add (FIG. 4), a block select circuit 23 that transfers an operating voltage to the memory cell array MCA according to an output signal of the address decoder 22, and a voltage select circuit 24.

The address decoder 22 includes a plurality of block select lines BLKSEL and a plurality of voltage select lines 33. For example, the address decoder 22 sequentially refers to a row address RA in the address register ADR (FIG. 4) in response to a control signal from the sequencer SQC and decodes this row address RA to cause a predetermined block select transistor 35 and a predetermined voltage select transistor 37 corresponding to the row address RA to be in an ON state, and cause the block select transistors 35 and the voltage select transistors 37 other than those to be in an OFF state. For example, voltages of the predetermined block select line BLKSEL and voltage select line 33 are set to be in an “H” state and voltages other than those are set to be in an “L” state. When a P-channel type transistor is used, not an N-channel type transistor, an inverse voltage is applied to these wirings.

In the illustrated example, in the address decoder 22, one block select line BLKSEL is disposed per memory block BLK. However, this configuration is appropriately changeable. For example, one block select line BLKSEL may be included in per two or more memory blocks BLK.

The block select circuit 23 includes a plurality of block selectors 34 corresponding to the memory blocks BLK. These plurality of block selectors 34 each include the plurality of block select transistors 35 corresponding to the word lines WL and the select gate lines (SGD, SGS, SGSb). The block select transistor 35 is, for example, a field-effect type high breakdown voltage transistor. The block select transistors 35 have drain electrodes each electrically connected to the corresponding word line WL or select gate line (SGD, SGS, SGSb). Source electrodes are each electrically connected to a voltage supply line 31 via a wiring CG and the voltage select circuit 24. The gate electrodes are connected to the corresponding block select line BLKSEL in common.

The block select circuit 23 further includes a plurality of transistors (not illustrated). These plurality of transistors are field-effect type high breakdown voltage transistors connected between the select gate lines (SGD, SGS, SGSb) and the voltage supply lines to which the ground voltage V_{SS} is applied. These plurality of transistors apply the select gate lines (SGD, SGS, SGSb) included in unselected memory blocks BLK with the ground voltage V_{SS}. The plurality of word lines WL included in the unselected memory blocks BLK enter a floating state.

The voltage select circuit 24 includes a plurality of voltage selectors 36 corresponding to the word lines WL and the select gate lines (SGD, SGS, SGSb). These plurality of voltage selectors 36 each include a plurality of voltage select transistors 37. The voltage select transistor 37 is, for example, a field-effect type high breakdown voltage transistor. The voltage select transistors 37 have drain terminals each electrically connected to the corresponding word line WL or select gate line (SGD, SGS, SGSb) via the wiring CG and the block select circuit 23. Source terminals are each electrically connected to the corresponding voltage supply line 31. The gate electrodes are each connected to the corresponding voltage select line 33.

### [Configuration of Sense Amplifier SA]

The sense amplifiers SA0, SA1 (FIG. 4) include sense amplifier modules SAM0, SAM1 and cache memories CM0, CM1 (data registers), respectively. The cache memories CM0, CM1 include latch circuits XDL0, XDL1, respectively. In the following description, the sense amplifier modules SAM0, SAM1 are referred to as a sense amplifier module SAM, the cache memories CM0, CM1 are referred to as a cache memory CM, and the latch circuits XDL0, XDL1 are referred to as a latch circuit XDL, in some cases.

For example, the sense amplifier module SAM includes sense circuits corresponding to the respective plurality of bit lines BL, a plurality of latch circuits connected to the sense circuits, and the like.

The cache memory CM includes a plurality of the latch circuits XDL. The respective plurality of latch circuits XDL are connected to the latch circuits inside the sense amplifier module SAM. In the latch circuit XDL, for example, user data Dat written into the memory cell MC or the user data Dat read out from the memory cell MC is stored.

For example, as illustrated in FIG. 7, a column decoder COLD is connected to the cache memory CM. More specifically, a column decoder COLD0 is connected to the cache memory CM0 included in the sense amplifier SA0 and a column decoder COLD1 is connected to the cache memory CM1 included in the sense amplifier SA1. The column decoder COLD decodes a column address CA stored in the address register ADR (FIG. 4) and selects the latch circuit XDL corresponding to the column address CA.

The user data Dat included in these plurality of latch circuits XDL are sequentially transferred to the latch circuits inside the sense amplifier modules SAM in the write operation. The user data Dat included in the latch circuits inside the sense amplifier modules SAM are sequentially transferred to the latch circuits XDL in the read operation. The user data Dat included in the latch circuits XDL are sequentially transferred to the input/output control circuit I/O via the column decoder COLD and a multiplexer MPX in a data-out operation.

### [Configuration of Voltage Generation Circuit VG]

For example, as illustrated in FIG. 5, the voltage generation circuit VG (FIG. 4) is connected to the plurality of voltage supply lines 31. The voltage generation circuit VG includes, for example, a step down circuit, such as a regulator, and a step up circuit, such as a charge pump circuit 32. These step down circuit and step up circuit are each connected to a voltage supply line to which the power supply voltage V_{CC} and the ground voltage V_{SS} (FIG. 4) are applied. The power supply voltage V_{CC} is, for example, 2.5 V and the ground voltage V_{SS} is, for example, 0 V. These voltage supply lines are connected to, for example, the pad electrodes P described with reference to FIG. 2 and FIG. 3. For example, the voltage generation circuit VG generates a plurality of operating voltages applied to the bit line BL, the source line SL, the word line WL, and the select gate lines (SGD, SGS, SGSb) in the read operation, the write operation, and the erase operation on the memory cell array MCA, in accordance with the control signal from the sequencer SQC to simultaneously output the operating voltages to the plurality of voltage supply lines 31. The operating voltage output from the voltage supply line 31 is appropriately adjusted in accordance with the control signal from the sequencer SQC. Note that the voltage generation circuit VG also generates a power supply voltage V_{DD} described later.

### [Configuration of Sequencer SQC]

In accordance with command data Cmd stored in the command register CMR, the sequencer SQC (FIG. 4) outputs an internal control signal to the row decoders RD0, RD1, the sense amplifier modules SAM0, SAM1, and the voltage generation circuit VG. The sequencer SQC outputs status data Stt indicating the state of the memory die MD to the status register STR as necessary.

The sequencer SQC generates a ready/busy signal and outputs the ready/busy signal to a terminal RY//BY. For example, the terminal RY//BY enters the “L” state during operations where a voltage is applied to the memory cell array MCA, such as the read operation, the write operation, and the erase operation, and enters the “H” state in the other cases. Even when the operation not applying a voltage to the memory cell array MCA, such as the data-out operation and a status read, are performed, the terminal RY//BY does not enter the “L” state. In a period where the terminal RY//BY is in the “L” state (busy period), an access to the memory die MD is basically inhibited. In a period where the terminal RY//BY is in the “H” state (ready period), the access to the memory die MD is permitted. The terminal RY//BY is achieved by, for example, the pad electrode P described with reference to FIG. 2 and FIG. 3.

### [Configuration of Address Register ADR]

As illustrated in FIG. 4, the address register ADR is connected to the input/output control circuit I/O and stores the address data Add input from the input/output control circuit I/O. For example, the address register ADR includes a plurality of 8-bit register strings. For example, when an internal operation, such as the read operation, the write operation, or the erase operation, is performed, the register string latches the address data Add corresponding to the internal operation in execution.

The address data Add, for example, includes the column address CA (FIG. 4) and the row address RA (FIG. 4). For example, the row address RA includes a block address to identify the memory block BLK (FIG. 5), a page address to identify the string unit SU and the word line WL, a plane address to identify the memory cell array MCA (plane), and a chip address to identify the memory die MD.

### [Configuration of Command Register CMR]

The command register CMR is connected to the input/output control circuit I/O and stores the command data Cmd input from the input/output control circuit I/O. For example, the command register CMR includes at least one set of an 8-bit register string. When the command data Cmd is stored in the command register CMR, the control signal is transmitted to the sequencer SQC.

### [Configuration of Status Register STR]

The status register STR is connected to the input/output control circuit I/O and stores the status data Stt output to the input/output control circuit I/O. For example, the status register STR includes a plurality of 8-bit register strings. For example, when the internal operation, such as the read operation, the write operation, or the erase operation, is performed, the register string latches the status data Stt regarding the internal operation in execution. The register string, for example, latches ready/busy information of the memory cell arrays MCA0, MCA1.

### [Configuration of Input/Output Control Circuit I/O]

For example, as illustrated in FIG. 8, the input/output control circuit I/O (FIG. 4) includes data signal input/output terminals DQ0 to DQ7, data strobe signal input/output terminals DQS, /DQS, a shift register, a plurality of the input circuits 210, the input circuit 220, the input buffer circuit 230, a plurality of output circuits 240, an output circuit 250, and an output buffer circuit 260. The input circuits 210, 220 are, for example, receivers (Input Receivers), such as comparators, and the output circuits 240, 250 are drivers, such as Off Chip Driver (OCD) circuits. At least a part of the input/output control circuit I/O is connected to a voltage supply line to which the input/output power supply voltage V_{CCQ} (FIG. 4) is applied. The input/output power supply voltage V_{CCQ} is, for example, 1.2 V.

Each of the data signal input/output terminals DQ0 to DQ7 and the data strobe signal input/output terminals DQS, /DQS is achieved by, for example, the pad electrode P described with reference to FIG. 2 and FIG. 3. Data input via the data signal input/output terminals DQ0 to DQ7 are input from the buffer circuit (for example, the input buffer circuit 230 in FIG. 8) to the cache memory CM, the address register ADR, or the command register CMR in response to the internal control signal from the logic circuit CTR. Data output via the data signal input/output terminals DQ0 to DQ7 are input to the buffer circuit (for example, the output buffer circuit 260 in FIG. 8) from the cache memory CM or the status register STR in response to the internal control signal from the logic circuit CTR.

Signals input via the data strobe signal input/output terminals DQS, /DQS (for example, a data strobe signal and its complementary signal) are used at data input via the data signal input/output terminals DQ0 to DQ7. The data input via the data signal input/output terminals DQ0 to DQ7 are taken in the shift register in the input/output control circuit I/O at a timing of a voltage rise edge of the data strobe signal input/output terminal DOS (switching of the input signal) and a voltage fall edge of the data strobe signal input/output terminal /DQS (switching of the input signal), and at a timing of a voltage fall edge of the data strobe signal input/output terminal DOS (switching of the input signal) and a voltage rise edge of the data strobe signal input/output terminal /DQS (switching of the input signal).

For example, as illustrated in FIG. 8, each of the data signal input/output terminals DQ0 to DQ7 is connected to the input circuit 210 and the output circuit 240. For example, as illustrated in FIG. 8, the data strobe signal input/output terminals DQS, /DQS are connected to the input circuit 220 and the output circuit 250, respectively.

For example, as illustrated in FIG. 9, the input circuit 210 includes the comparator 211 and a signal propagation circuit 212. The comparator 211 has one input terminal connected to any of the data signal input/output terminals DQ0 to DQ7, and the other input terminal connected to a voltage supply line that applies the reference voltage (reference signal) VREF. The signal propagation circuit 212 propagates the output signal of the comparator 211. A signal Din propagated by the signal propagation circuit 212 corresponds to the data and the like input via the data signal input/output terminals DQ0 to DQ7.

For example, as illustrated in FIG. 9, the input circuit 220 includes a comparator 221 and signal propagation circuits 222, 223. The comparator 221 has one input terminal connected to the data strobe signal input/output terminal DOS, and the other input terminal connected to the data strobe signal input/output terminal /DQS. The signal propagation circuits 222, 223 propagate the output signal of the comparator 221. The signal propagation circuits 222, 223 propagate signals Sig1, Sig2. The signals Sig1, Sig2 are data strobe signals input via the data strobe signal input/output terminals DQS, /DQS. That is, the signals Sig1, Sig2 are timing control signals that control a timing of retrieving data and also function as so-called clock signals. The signal Sig2 is an inverted signal of the signal Sig1.

For example, as illustrated in FIG. 9, the input buffer circuit 230 includes a latch circuit 230e and a latch circuit 2300. The latch circuit 230e latches even-numbered data included in the signal Din. The latch circuit 2300 latches odd-numbered data included in the signal Din.

The output circuits 240, 250 (FIG. 8) include OCD circuits and the like. The output buffer circuit 260 includes a latch circuit and the like. Detailed configurations of the output circuits 240, 250 and the output buffer circuit 260 is omitted.

For example, as illustrated in FIG. 10A, the comparator 211 (FIG. 9) of the input circuit 210 includes the first amplifier 300 and a second amplifier 310. The first amplifier 300 is a single input·differential output type amplifier. The first amplifier 300 includes a differential circuit 303, a load circuit 301, and the source follower circuit 302.

The differential circuit 303 and the load circuit 301 are electrically connected to one another via a second node N2 and a fourth node N4. The differential circuit 303 and the load circuit 301 constitute a differential amplifier. A first node N1 and a third node N3 are connected to P side and N side input terminals in the differential amplifier, respectively. The second node N2 and the fourth node N4 are connected to P side and N side output terminals in the differential amplifier, respectively. The P side input terminal is connected to any of the data signal input/output terminals DQ0 to DQ7 and the N side input terminal is connected to the voltage supply line that applies the reference voltage (reference signal) VREF.

A data signal INP (DQ) corresponds to a data signal input via the P side input terminal (any of the data signal input/output terminals DQ0 to DQ7). The data signal INP (DQ) swings according to a logic level of data between the input/output power supply voltage V_{CCQ} (for example, 1.2 V) and the ground voltage V_{SS} (for example, 0 V). The reference voltage (reference signal) VREF corresponds to the reference voltage input via the N side input terminal. The reference voltage VREF is a DC voltage around a half of an amplitude of the data signal INP (DQ) (the input/output power supply voltage V_{CCQ}, for example, 1.2 V) (for example, 0.6 V). A P side signal OUTP corresponds to an output signal output via the P side output terminal. An N side signal OUTN corresponds to an output signal output via the N side output terminal. The first amplifier 300 inputs the data signal INP and the reference voltage VREF, generates the P side signal OUTP and the N side signal OUTN according to the data signal INP, and outputs the P side signal OUTP and the N side signal OUTN to the second amplifier 310 via the second node N2 and the fourth node N4.

The differential circuit 303 is disposed between the power supply voltage V_{DD} and the load circuit 301. The differential circuit 303 includes transistors M10, M11 and a current source CS. The transistors M10, M11 are constituted by PMOS transistors (P type MOS transistors). The transistors M10, M11 constitute a differential pair.

The transistor M10 has a gate electrode electrically connected to the first node N1 that inputs the data signal INP, a source electrode electrically connected to a node NC, and a drain electrode is electrically connected to the second node N2. Additionally, the transistor M11 has a gate electrode electrically connected to the third node N3 that inputs the reference voltage VREF, a source electrode electrically connected to the node NC, and a drain electrode electrically connected to the fourth node N4.

The current source CS is electrically connected between the power supply voltage V_{DD} and the node NC. The current source C is constituted by, for example, a transistor M1. The transistor M1 is constituted by a PMOS transistor (P type MOS transistor). The transistor M1 has a gate electrode electrically connected to a signal line that inputs a signal PBIAS (bias signal), a source electrode electrically connected to the power supply voltage V_{DD}, and a drain electrode electrically connected to the node NC.

The load circuit 301 is disposed between the differential circuit 303 and the ground voltage V_{SS}. The load circuit 301 includes a first impedance Z0 and a second impedance Z1. The first impedance Z0 is electrically connected between the second node N2 and the ground voltage V_{SS}. The second impedance Z1 is electrically connected between the fourth node N4 and the ground voltage V_{SS}. Note that each of the first impedance Z0 and the second impedance Z1 may be constituted by a resistor element.

The source follower circuit 302 is connected in parallel with the differential circuit 303. The source follower circuit 302 includes transistors M20, M30, a first current restriction circuit CL1, and a second current restriction circuit CL2.

The first current restriction circuit CL1 is, for example, constituted by a transistor M2. The second current restriction circuit CL2 is, for example, constituted by a transistor M3. The transistors M2, M3 are constituted by PMOS transistors (P type MOS transistors). The transistor M2 has a gate electrode electrically connected to a signal line that inputs the signal PBIAS, a source electrode electrically connected to the power supply voltage V_{DD}, and a drain electrode electrically connected to a drain electrode of the transistor M20. The transistor M3 has a gate electrode electrically connected to the signal line that inputs the signal PBIAS, a source electrode electrically connected to the power supply voltage V_{DD}, and a drain electrode electrically connected to a drain electrode of the transistor M30.

The transistors M20, M30 are constituted by NMOS transistors (N type MOS transistors). The transistor M20 has a gate electrode electrically connected to the first node N1 that inputs the data signal INP, a drain electrode electrically connected to the drain electrode of the transistor M2, and a source electrode electrically connected to the fourth node N4. The transistor M30 has a gate electrode electrically connected to the third node N3 that inputs the reference voltage VREF, a drain electrode electrically connected to the drain electrode of the transistor M3, and a source electrode electrically connected to the second node N2.

The second amplifier 310 is a differential input·single output type amplifier. The second amplifier 310 has one input terminal electrically connected to the second node N2 of the first amplifier 300 and the other input terminal electrically connected to the fourth node N4 of the first amplifier 300. The second amplifier 310 inputs the P side signal OUTP and the N side signal OUTN as a differential signal, generates an output signal BUF_OUT according to the P side signal OUTP and the N side signal OUTN, and outputs the output signal BUF_OUT to the signal propagation circuit 212 (FIG. 9). The detailed configuration of the second amplifier 310 is omitted.

### [Configuration of Logic Circuit CTR]

The logic circuit CTR (FIG. 4) includes a plurality of external control terminals /CE, CLE, ALE, /WE, /RE, RE and a logic circuit connected to these plurality of external control terminals /CE, CLE, ALE, /WE, /RE, RE. The logic circuit CTR inputs an external control signal from the controller die CD via the external control terminals /CE, CLE, ALE, /WE, /RE, RE and outputs the internal control signal to the input/output control circuit I/O in response to this.

Note that, for example, each of the external control terminals /CE, CLE, ALE, /WE, /RE, RE is achieved by the pad electrode P described with reference to FIG. 2 and FIG. 3.

A signal input via the external control terminal /CE (for example, a chip enable signal) is used in selection of the memory die MD. The memory die MD where “L” is input to the external control terminal /CE enters a state where the input and output of the user data Dat, the command data Cmd, and the address data Add (hereinafter simply referred to as “data” in some cases) are possible. The memory die MD where “H” is input to the external control terminal /CE enters a state where the input and output of the data are difficult.

A signal input via an external control terminal CLE (for example, a command latch enable signal) is used to indicate that data input via the data signal input/output terminals DQ0 to DQ7 is the command data Cmd. When “H” is input to the external control terminal CLE, data input via the data signal input/output terminals DQ0 to DQ7 is stored in a buffer memory in the input/output control circuit I/O as the command data Cmd and is transferred to the command register CMR.

A signal input via an external control terminal ALE (for example, an address latch enable signal) is used to indicate that data input via the data signal input/output terminals DQ0 to DQ7 is the address data Add. When “H” is input to the external control terminal ALE, data input via the data signal input/output terminals DQ0 to DQ7 is stored in the buffer memory in the input/output control circuit I/O as the address data Add and is transferred to the address register ADR.

When “L” is input to both of the external control terminals CLE, ALE, the data input via the data signal input/output terminals DQ0 to DQ7 is stored as the user data Dat in the buffer memory in the input/output control circuit I/O. The user data Dat is transferred to the cache memory CM via a bus DB.

A signal input via the external control terminal /WE (for example, a write enable signal) is used to input data via the data signal input/output terminals DQ0 to DQ7. The data input via the data signal input/output terminals DQ0 to DQ7 is retrieved in the shift register in the input/output control circuit I/O at a timing of a voltage rise (switching of the input signal) of the external control terminal /WE.

When the data is input, the external control terminal /WE may be used, or the data strobe signal input/output terminals DOS, /DQS may be used.

A signal input via the external control terminals /RE, RE (for example, a read enable signal and a complementary signal thereof) is used to output data via the data signal input/output terminals DQ0 to DQ7. The data output from the data signal input/output terminals DQ0 to DQ7 is switched at a timing of a voltage fall edge of the external control terminal /RE (switching of the input signal) and a voltage rise edge of the external control terminal RE (switching of the input signal) and a timing of a voltage rise edge of the external control terminal /RE (switching of the input signal) and a voltage fall edge of the external control terminal RE (switching of the input signal).

### [Input Example of Data Signal in Write Operation]

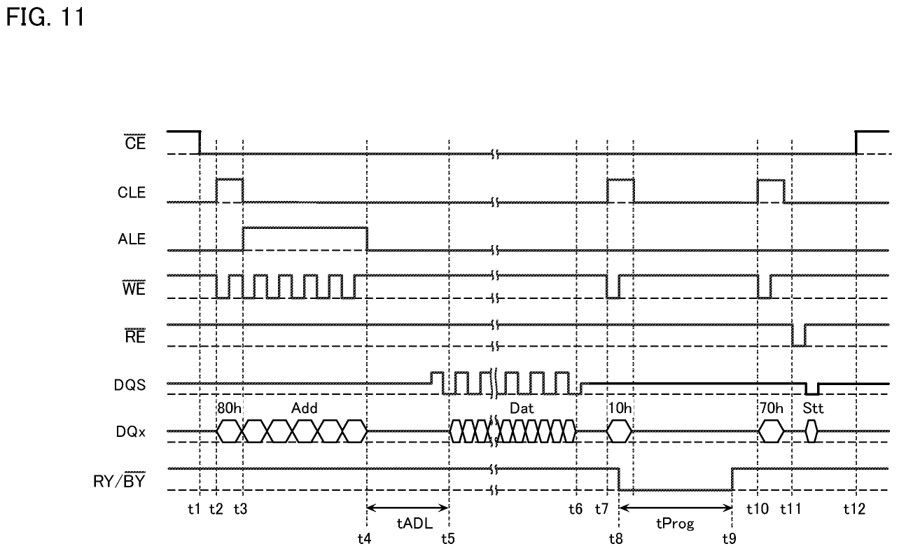

FIG. 11 is a timing chart illustrating the input example of the data signal in the write operation. Note that “x” of a data signal input/output terminal DQx is a number from 0 to 7.

At timing t1 in FIG. 11, the chip enable signal input via the external control terminal /CE switches from “H” to “L”. Thus, the memory die MD enters a state in which data can be input and output.

At timing t2, the command latch enable signal input via the external control terminal CLE switches from “L” to “H”. Afterwards, at a timing of rise of the write enable signal input via the external control terminal /WE, command data “80 h” input via the data signal input/output terminal DQx is retrieved and transferred to the command register CMR (FIG. 4). The command data “80 h” is the command data Cmd input at a start of the command set instructing the write operation.

At timing t3, the command latch enable signal input via the external control terminal CLE switches from “H” to “L” and the address latch enable signal input via the external control terminal ALE switches from “L” to “H”. Afterwards, at a timing of rise of the write enable signal input via the external control terminal /WE, the address data Add input via the data signal input/output terminal DQx is retrieved and transferred to the address register ADR (FIG. 4).

At timing t4, the address latch enable signal input via the external control terminal ALE switches from “H” to “L” and retrieving the address data Add terminates. In the illustrated example, from timing t3 to timing t4, while the data of 8 bits×5 cycles constituting the address data Add is input, the number of cycles may be less than or more than five.

Timing t4 to timing t5 are a preparation period of the cache memory CM (data register) (a period denoted as “tADL” in FIG. 11).

At timing t5, the user data Dat input via the data signal input/output terminals DQ0 to DQ7, for example, is retrieved at a timing of the voltage rise edge of the data strobe signal input/output terminal DOS and the voltage fall edge of the data strobe signal input/output terminal /DQS and transferred to the cache memory CM. In the illustrated example, the user data Dat is retrieved from timing t5 to timing t6.

The write operation is performed in units of pages. When one page is 16 k bytes, an amount of the user data Dat on which the write operation is performed is 16 k bytes. In this case, from timing t5 to timing t6, the data of 8 bits×16 k cycles constituting the user data Dat is input.

At timing t7, the command latch enable signal input via the external control terminal CLE switches from “L” to “H”. Afterwards, at a timing of the rise of the write enable signal input via the external control terminal /WE, command data “10 h” input via the data signal input/output terminal DQx is retrieved and transferred to the command register CMR (FIG. 4). The command data “10 h” is the command data Cmd input at an end of the command set to instruct the write operation.

At timing t8, the write operation starts. In the illustrated example, the write operation is performed in a period from timing t8 to timing t9 (a period denoted as “tProg” in FIG. 11). In this period, the terminal RY//BY is controlled to be in the “L” state.

At timing t10, the command latch enable signal input via the external control terminal CLE switches from “L” to “H”. Afterwards, at a timing of the rise of the write enable signal input via the external control terminal /WE, command data “70 h” input via the data signal input/output terminal DQx is retrieved and transferred to the command register CMR (FIG. 4). The command data “70 h” is command data to instruct status read. The status read is an operation of outputting status data Stt included in the status register STR to the controller die CD.

In association with the input of the command data “70 h”, at timing t11, status read is performed, and the status data Stt is output via the data signal input/output terminal DQx. In this case, the status data Stt, for example, includes data indicative of whether the user data Dat is normally written in the write operation or not.

At timing t12, the chip enable signal input via the external control terminal /CE switches from “L” to “H”. Thus, data cannot be input and output to the memory die MD.

### [Operation of Comparator 211]

Next, with reference to FIG. 10A to FIG. 10C and FIG. 12A to FIG. 14D, the operation of the comparator 211 (FIG. 10A) is described.

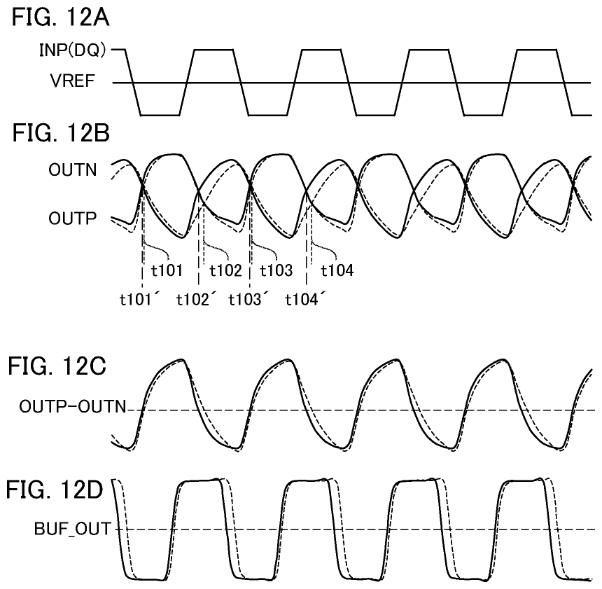

FIG. 12A to FIG. 14D are waveform diagrams illustrating the operation of the comparator 211. Note that the operation of the comparator 211 illustrated in FIG. 12A to FIG. 14D is, for example, the operation from timing t5 to timing t6 in FIG. 11 (the input operation of the user data Dat).

FIG. 12A illustrates waveforms of the data signal INP (DQ) and the reference voltage VREF. FIG. 12B illustrates waveforms of the P side signal OUTP and the N side signal OUTN as the differential signal input to the second amplifier 310. FIG. 12C illustrates a waveform of the differential signal between the P side signal OUTP and the N side signal OUTN (OUTP-OUTN). FIG. 12D illustrates a waveform of the output signal BUF_OUT. Note that in FIG. 12A, the data signal INP is a waveform of the data signal INP that regularly repeats “H” and “L” (that is, “1” and “0”). In FIG. 12B to FIG. 12D, the dotted line indicates a waveform of each signal when the source follower circuit 302 is not added to the differential amplifier (the differential circuit 303 and the load circuit 301) (FIG. 10B), and the solid line indicates a waveform of each signal when the source follower circuit 302 is added to the differential amplifier (the differential circuit 303 and the load circuit 301) (FIG. 10A).

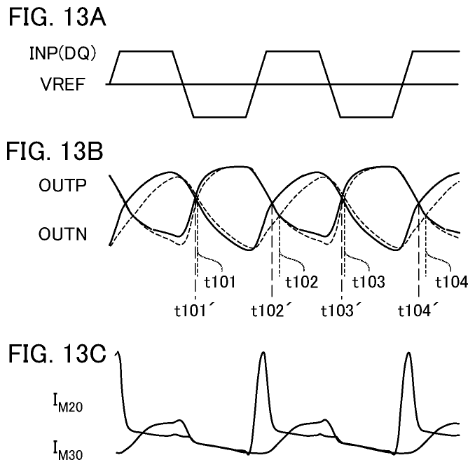

FIG. 13A and FIG. 13B are enlarged views of enlarging a part of the waveforms of FIG. 12A and FIG. 12B. FIG. 13C illustrates waveforms of drain currents I_{M20}, I_{M30} of the transistors M20, M30.

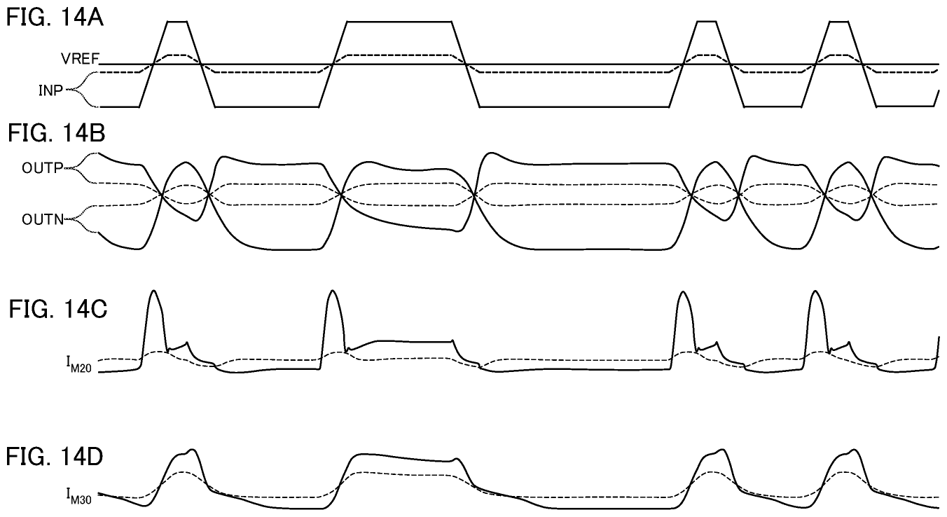

FIG. 14A illustrates waveforms of the data signal INP and the reference voltage VREF. FIG. 14B illustrates waveforms of the P side signal OUTP and the N side signal OUTN. FIG. 14C illustrates a waveform of the drain current I_{M20} of the transistor M20. FIG. 14D illustrates a waveform of the drain current I_{M30} of the transistor M30. Note that in FIG. 14A to FIG. 14D, the solid line indicates the waveform of each signal when an amplitude of the data signal INP is large, and the dotted line indicates the waveform of each signal when an amplitude of the data signal INP is small. FIG. 14A is a waveform of the data signal INP in which “H” and “L” irregularly appear.

[Case where Source Follower Circuit 302 is not Added to Differential Amplifier]

Here, the operation of the differential amplifier, that is, the operation of the first amplifier 300G described with reference to FIG. 10B is described.

A signal PBIAS at a predetermined voltage is input to a gate electrode of the transistor M1 (current source CS). Thus, the transistor M1 is in the ON state.

As illustrated in FIG. 12A, when the data signal INP rises (that is, when the data signal INP turns “H” from “L”), among the currents supplied from the transistor M1 to the node NC, the current flowing through the transistor M10 gradually decreases and the current flowing through the transistor M11 gradually increases. By the gradual decrease in the current flowing through the transistor M10, a voltage drop in the first impedance Z0 decreases to gradually lower an electrical potential of the second node N2. Therefore, as indicated by the waveform of the dotted line of FIG. 12B, the voltage of the P side signal OUTP gradually decreases. Additionally, by the gradual increase in the current flowing through the transistor M11, a voltage drop in the second impedance Z1 increases to gradually increase an electrical potential of the fourth node N4. Therefore, as indicated by the waveform of the dotted line of FIG. 12B, the voltage of the N side signal OUTN gradually increases.

As illustrated in FIG. 12A, when the data signal INP falls (that is, the data signal INP turns “L” from “H”), among the currents supplied from the transistor M1 to the node NC, the current flowing through the transistor M10 gradually increases and the current flowing through the transistor M11 gradually decreases. By the gradual increase in the current flowing through the transistor M10, a voltage drop in the first impedance Z0 increases to gradually increase an electrical potential of the second node N2. Therefore, as indicated by the dotted line waveform of FIG. 12B, the voltage of the P side signal OUTP gradually increases. Additionally, by the gradual decrease in the current flowing through the transistor M11, a voltage drop in the second impedance Z1 decreases to gradually lower an electrical potential of the fourth node N4. Therefore, as indicated by the dotted line waveform of FIG. 12B, the voltage of the N side signal OUTN gradually decreases.

Thus, the first amplifier 300G as the differential amplifier converts the data signal INP as a single-phase digital signal into the P side signal OUTP and the N side signal OUTN as the differential signal.

As indicated by the dotted line waveform of FIG. 12C, the second amplifier 310 generates a differential signal between the P side signal OUTP and the N side signal OUTN (OUTP-OUTN) based on the P side signal OUTP and the N side signal OUTN. As indicated by the dotted line waveform of FIG. 12D, the second amplifier 310 generates the output signal BUF_OUT based on the differential signal (OUTP−OUTN) and outputs the generated output signal BUF_OUT to the signal propagation circuit 212.

### [Asymmetry of Rise and Fall Operations of Data Signal INP in Differential Amplifier]

Similar to the above-described case, the transistor M1 constituting the current source CS is in the ON state.

As described above, when the data signal INP falls (that is, the data signal INP turns “L” from “H”), the current flowing through the transistor M10 increases. Here, the gate electrode of the transistor M10 is connected to the first node N1. That is, since the ground voltage (for example, 0 V) is applied to the gate electrode of the transistor M10, an amount of drive comparatively increases. Therefore, when the data signal INP falls, a gate-source voltage (a value found by subtracting the source voltage from the gate voltage) of the transistor M10 decreases. Additionally, at this timing, an electric charge of a parasitic capacitance of the node NC (the node to which the source electrodes of the transistors M10, M11 are connected in common) passes through the transistor M10 and flows in the second node N2 all at once. Therefore, the second node N2 is rapidly charged. Therefore, as indicated by the dotted line waveforms of FIG. 12B and FIG. 13B, the P side signal OUTP rapidly rises according to the fall of the data signal INP.

As described above, when the data signal INP rises (that is, the data signal INP turns “H” from “L”), the current flowing through the transistor M11 increases. Here, the gate electrode of the transistor M11 is connected to the third node N3. That is, to the gate electrode of the transistor M11, the reference voltage VREF (for example, 0.6 V) is applied, and therefore the amount of drive comparatively decreases. Therefore, when the data signal INP rises, first, the current flowing through the transistor M10 decreases, the node N2 is charged, and thus, the gate-source voltage of the transistor M11 decreases. Therefore, the fourth node N4 is charged slower than the second node N2. Therefore, as indicated by the dotted line waveforms of FIG. 12B and FIG. 13B, the N side signal OUTN rises slowly according to the rise of the data signal INP.

Thus, a speed at which the fourth node N4 is charged is slower than a speed at which the second node N2 is charged. That is, operations of rise and fall of the data signal INP in the differential amplifier becomes asymmetric. The asymmetry of the operations significantly occurs when the amplitude of the data signal INP is large and a slew rate of the data signal INP is high.

Note that a speed at which the second node N2 is discharged (a speed of fall of the P side signal OUTP) when the data signal INP rises is approximately the same as a speed at which the fourth node N4 is discharged (a speed of falling of the N side signal OUTN) when the data signal INP falls.

As indicated by the dotted line waveforms of FIG. 12B and FIG. 13B, the P side signal OUTP and the N side signal OUTN change signs at intersection points of them (timings t101, t102, t103, and t104). Voltage values of the P side signal OUTP and the N side signal OUTN in the timings t101, t103 are higher than voltage values of the P side signal OUTP and the N side signal OUTN in the timings t102, t104. A period from timing t101 to timing t102 is longer than a period from timing t102 to timing t103. Thus, in the P side signal OUTP and the N side signal OUTN as the differential signal, a jitter (displacement and fluctuation in a time axis direction occurred when the signal is transmitted) occurs. As a result, as indicated by the dotted line waveform of FIG. 12D, in the output signal BUF_OUT, a part where the pulse width is large (H pulse width) and a part where the pulse width is small occur.

In the output signal BUF_OUT, a part where the voltage is larger than a center voltage of the pulse is referred to as an H pulse and a part where the voltage is smaller than the center voltage of the pulse is referred to as an L pulse in some cases. In the example of the dotted line waveform of FIG. 12D, the width of the H pulse is large and the width of the L pulse is small.

[Case where Source Follower Circuit 302 is Added to Differential Amplifier]

Here, the operation of the first amplifier 300 described with reference to FIG. 10A, that is, the operation when the source follower circuit 302 is added to the differential amplifier is described.

Similar to the case described above, the transistor M1 constituting the current source CS is in the ON state. Additionally, the transistor M2 constituting the first current restriction circuit CL1 is also in the ON state, and the transistor M3 constituting the second current restriction circuit CL2 is also in the ON state.

As illustrated in FIG. 12A, when the data signal INP rises (that is, when the data signal INP turns “H” from “L”), the current flowing through the transistor M10 decreases at a certain time point. At this time, the reference voltage VREF (for example, 0.6 V) is applied to the gate electrode of the transistor M11. Accordingly, a driving force of the transistor M11 is small and the current flowing through the transistor M11 does not rapidly increase.

Therefore, a driving force of the transistor M20 of the source follower circuit 302 complements the driving force of the transistor M11. That is, when the data signal INP turns “H” from “L”, the current flowing through the transistor M20 increases. Here, the gate electrode of the transistor M20 is connected to the first node N1. That is, to the gate electrode of the transistor M20, the input/output power supply voltage V_{CCQ} (for example, 1.2 V) is applied. Accordingly, when the data signal INP rises, the gate-source voltage of the transistor M20 increases. Accordingly, the current of the transistor M20 increases comparatively rapidly. As illustrated in FIG. 13C, the drain current I_{M20} of the transistor M20 is current having a large peak value. This drain current I_{M20} is supplied to the fourth node N4. At this time, to the second impedance, the current from the transistor M11 and the drain current I_{M20} from the transistor M20 flow. Therefore, the fourth node N4 is rapidly charged. As indicated by the solid line waveforms of FIG. 12B and FIG. 13B, the N side signal OUTN rapidly rises.

Here, a gate electrode of the transistor M30 is connected to the third node N3. That is, to the gate electrode of the transistor M30, the reference voltage VREF (for example, 0.6 V) is applied. At a stage of starting the rise of the data signal INP, since a voltage level of the P side signal OUTP is large, the gate-source voltage of the transistor M30 does not increase. Accordingly, the transistor M30 does not inhibit the fall of the P side signal OUTP at least until a timing at which the P side signal OUTP intersects with the N side signal OUTN.

As illustrated in FIG. 12A, when the data signal INP falls (that is, when the data signal INP turns “L” from “H”), the current flowing through the transistor M10 increases at a certain time point. In accordance with this, the current flowing through the transistor M11 decreases. At this time, to the gate electrode of the transistor M10, the input/output power supply voltage V_{CCQ} (for example, 1.2 V) is applied. Therefore, a driving force of the transistor M10 is large, and the current flowing through the transistor M10 rapidly increases.

As described above, the driving force of the transistor M10 is large and the second node N2 is rapidly charged, and thus originally the driving force of the transistor M10 need not be complemented. However, in this embodiment, the transistor M30 is disposed in the source follower circuit 302.

When the voltage same as the reference voltage VREF is input as the data signal INP, the difference between the P side signal OUTP and the N side signal OUTN need to be 0 V. When the difference between the P side signal OUTP and the N side signal OUTN is displaced from 0 V, the displacement is referred to as a DC offset. Here, when only the transistor M20 is disposed in the source follower circuit 302, the N side signal OUTN becomes larger than the P side signal OUTP and the DC offset occurs. Thus, to eliminate the DC offset, the transistor M30 is disposed in the source follower circuit 302.

Note that to the gate electrode of the transistor M30 of the source follower circuit 302, the reference voltage VREF (for example, 0.6 V) is applied. Therefore, the driving force of the transistor M30 is small. As illustrated in FIG. 13C, the drain current I_{M30} of the transistor M30 is current having a small peak value. This drain current I_{M30} is supplied to the second node N2. At this time, the second node N2 is rapidly charged by the current from the transistor M10 and the drain current I_{M30} from the transistor M30. As indicated by the solid line waveforms of FIG. 12B and FIG. 13B, the P side signal OUTP rapidly rises.

With the configuration, as indicated by the solid line waveforms of FIG. 12B and FIG. 13B, voltage values of the P side signal OUTP and the N side signal OUTN at timings t101′, t103′ are values close to the voltage values of the P side signal OUTP and the N side signal OUTN at timings t102′, t104′. A period from timing t101′ to timing t102′ has a length close to a period from timing t102′ to timing t103′. Thus, a jitter is reduced in the P side signal OUTP and the N side signal OUTN as the differential signal. As a result, as indicated by the solid line waveform of FIG. 12D, in the output signal BUF_OUT, the pulse width is approximately equal.

Note that the transistors M2, M3 constituting the current restriction circuit restricts the amount of current supplied to the nodes N5, N3 by the transistors M20, M30. This is to reduce excessive supply of current to the nodes N5, N3 by the transistors M20, M30.

### [When Data Signal INP is Irregular Data]

The first amplifier 300 is applicable not only in a case where the data signal INP in which the data signal INP regularly repeats “H” and “L” is input as illustrated in FIG. 12A, but also a case where the data signal INP in which “H” and “L” irregularly appear is input as illustrated in FIG. 14A.

[Cases where Amplitude of Data Signal INP is Large and Small]

As indicated by the solid line waveforms of FIG. 14A, FIG. 14B, FIG. 14C, and FIG. 14D, when the amplitude of the data signal INP is large, similarly to the case described with reference to FIG. 12A, FIG. 12B, FIG. 12C, FIG. 12D and FIG. 13A, FIG. 13B, and FIG. 13C, the drain currents I_{M20}, I_{M30} of the transistors M20, M30 are supplied to the nodes N5, N3, respectively, and thus both the P side signal OUTP and the N side signal OUTN rapidly rise. Therefore, a jitter is reduced in the P side signal OUTP and the N side signal OUTN, and the pulse width approximately equals in the output signal BUF_OUT.

Meanwhile, as indicated by the dotted line waveforms of FIG. 14A and FIG. 14B, when the amplitude of the data signal INP is small, speeds of the charge and discharge of the fourth node N4 according to the data signal INP are approximately the same as speeds of charge and discharge of the second node N2 according to the data signal INP. That is, the operations of rise and fall of the data signal INP in the differential amplifier are symmetry.

As indicated in the dotted line waveforms of FIG. 14C and FIG. 14D, when the amplitude of the data signal INP is small, since the voltage of the data signal INP input to the gate electrode of the transistor M20 is small, the drain current I_{M20} also decreases. Since the voltage input to the gate electrode of the transistor M30 is the reference voltage VREF, the drain current I_{M30} of the transistor M30 is also small. Thus, when the amplitude of the data signal INP is small, the drain current I_{M20}, I_{M30} need not be supplied to the node N5, N3. In this case, both the drain currents I_{M20}, I_{M30} are reduced to be small values.

### [Effects]

In association with the increased interface speed of the semiconductor memory device, it is necessary to reduce jitter that occurs in the input circuit 210 amplifying the input data signal INP. When the single-phase digital signal (data signal INP) is amplified in the input circuit 210, asymmetry of responses to the rise and the fall of the single-phase digital signal in the differential amplifier (the P side signal OUTP and the N side signal OUTN) causes Duty Cycle distortion (DCD), and thus problems arises in that a jitter occurs and the pulse width decreases. Especially, in the input circuit 210 for high-speed interface, the data signals INP at various amplitudes and slew rates need to be amplified over a wide band, and thus countermeasures against DCD are important.

In the first embodiment, the source follower circuit 302 is connected in parallel with the differential amplifier and the input signals (INP, VREF) to the gate electrodes of the transistors M20, M30 included in the source follower circuit 302 and the input signals to the gate electrodes of the transistors M10, M11 included in the differential amplifier are connected in common. The source follower performs a class B amplification operation so as to complement the difference in the response between the rise and the fall of the differential amplifier. This configuration also allows reducing DCD, allows reducing a jitter, and allows reducing a decrease in the pulse width.

### Second Embodiment

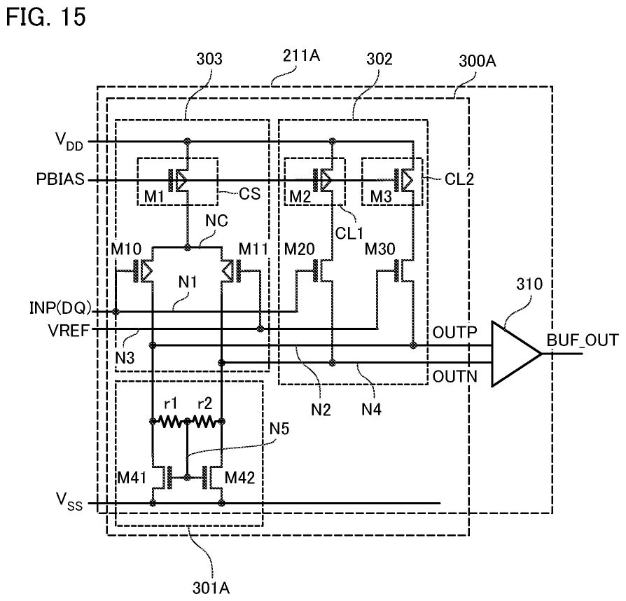

Next, with reference to FIG. 15, a configuration of a semiconductor memory device according to the second embodiment is described.

FIG. 15 is a schematic circuit diagram illustrating a configuration of a comparator 211A according to the second embodiment. Note that the configuration of the comparator 211A according to the second embodiment in FIG. 15 is basically the same as the configuration of the comparator 211 according to the first embodiment of FIG. 10A. However, in the comparator 211A according to the second embodiment, a load circuit 301A is disposed instead of the load circuit 301 (FIG. 10A). Additionally, a first amplifier 300A is used instead of the first amplifier 300.

The load circuit 301A includes transistors M41, M42 and resistor elements r1, r2. The transistors M41, M42 are constituted by NMOS transistors. The transistor M41 has a drain electrode electrically connected to the second node N2, a source electrode electrically connected to the ground voltage V_{SS}, and a gate electrode electrically connected to a fifth node N5. The transistor M42 has a drain electrode electrically connected to the fourth node N4, a source electrode electrically connected to the ground voltage V_{SS}, and a gate electrode electrically connected to the fifth node N5. The resistor element r1 is electrically connected between the second node N2 and the fifth node N5. The resistor element r2 is electrically connected to the fourth node N4 and the fifth node N5.

With the configuration, since the voltages of the second node N2 and the fourth node N4 are determined by the voltages V_{GS} (the gate-source voltages) of the transistors M41, M42, they are less likely to be influenced by the magnitudes of the currents flowing through the second node N2 and the fourth node N4, and the voltages of the second node N2 and the fourth node N4 are likely to stabilize. Additionally, by stabilizing the voltages of the second node N2 and the fourth node N4, the voltages of the source electrodes of the transistors M20, M30 stabilize and the voltages V_{GS} (gate-source voltages) of the transistors M20, M30 stabilize. Accordingly, the transistors M20, M30 can reliably complement the driving forces of the transistors M10, M11.

### Third Embodiment

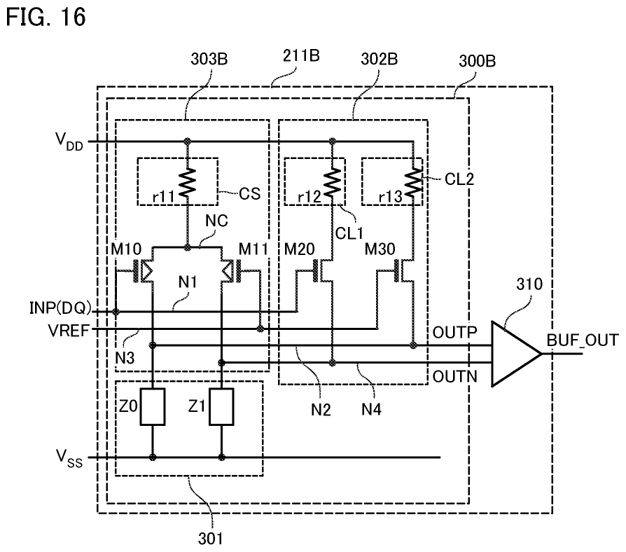

Next, with reference to FIG. 16, a configuration of a semiconductor memory device according to third embodiment is described.

FIG. 16 is a schematic circuit diagram illustrating a configuration of a comparator 211B according to the third embodiment. Note that the configuration of the comparator 211B according to third embodiment of FIG. 16 is basically the same as the configuration of the comparator 211 according to the first embodiment of FIG. 10A. However, in the comparator 211B according to third embodiment, a differential circuit 303B is used instead of the differential circuit 303. In the differential circuit 303B, the transistor M1 constituting the current source CS is replaced by a resistor element r11, the transistor M2 constituting the first current restriction circuit CL1 is replaced by a resistor element r12, and the transistor M3 constituting the second current restriction circuit CL2 is replaced by a resistor element r13. Additionally, a source follower circuit 302B is used instead of the source follower circuit 302. A first amplifier 300B is used instead of the first amplifier 300.

This configuration also allows reducing DCD, allows reducing a jitter, and allows reducing a decrease in the pulse width.

### Fourth Embodiment

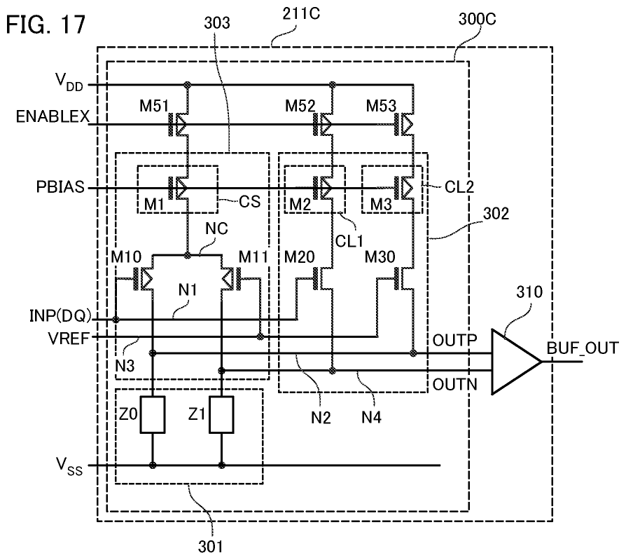

Next, with reference to FIG. 17, a configuration of a semiconductor memory device according to fourth embodiment is described.

FIG. 17 is a schematic circuit diagram illustrating a configuration of a comparator 211C according to the fourth embodiment. Note that the configuration of the comparator 211C according to fourth embodiment of FIG. 17 is basically the same as the configuration of the comparator 211 according to the first embodiment of FIG. 10A. However, in the comparator 211B according to fourth embodiment, a first amplifier 300C includes a first switch transistor M51 electrically connected between the power supply voltage V_{DD} and the current source CS, a second switch transistor M52 electrically connected between the power supply voltage V_{DD} and the first current restriction circuit CL1, and a third switch transistor M53 electrically connected between the power supply voltage V_{DD} and the second current restriction circuit CL2.

Each of the switch transistors M51, M52, M53 is constituted by a PMOS transistor. Additionally, a gate electrode of each of the switch transistors M51, M52, M53 is electrically connected to a signal line that inputs a signal ENABLEX.

With the configuration, by switching the signal ENABLEX, an ON·OFF state of the differential amplifier (the differential circuit 303 and the load circuit 301) can be controlled, an ON·OFF state of the transistors M2, M20 can be controlled, and an ON·OFF state of the transistors M3, M30 can be controlled.

### Fifth Embodiment

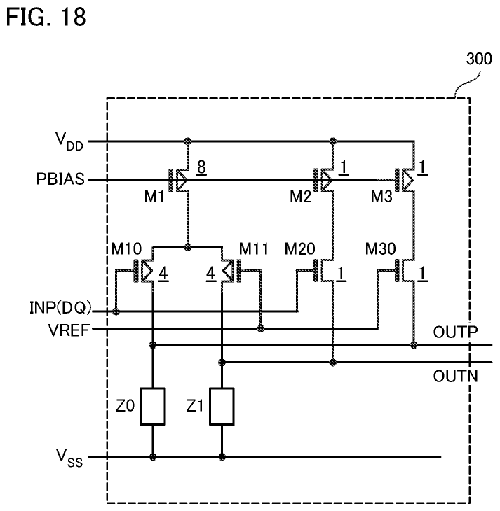

Next, with reference to FIG. 18, a configuration of a semiconductor memory device according to the fifth embodiment is described.

FIG. 18 is a schematic circuit diagram illustrating the configuration of the first amplifier 300 according to the fifth embodiment. FIG. 18 denotes the size of the transistor constituting the first amplifier 300. Note that the configuration of the first amplifier 300 according to the fifth embodiment in FIG. 18 is the same as the configuration of the first amplifier 300 according to the first embodiment in FIG. 10A.

In FIG. 18, the respective transistors M1, M2, M3, M10, M11, M20, M30 included in the first amplifier 300 are constituted by very low voltage transistors. A number given to the side of each of the transistors in FIG. 18 indicates a ratio of a width (gate width) of a gate region of each of the transistors. The ratios of the widths of the gate regions of the transistors M2, M3, M20, M30 are “1”. The ratios of the widths of the gate regions of the transistors M10, M11 are “4”. The ratio of the width of the gate region of the transistor M1 is “8”.

Note that the number given to the side of each of the transistors in FIG. 18 may be the number of fingers of each of the transistors. The number of fingers means the number of connections of the very low voltage transistors in parallel. The number of fingers of the transistors M2, M3, M20, M30 is “1”. The number of fingers of the transistors M10, M11 is “4”. The number of fingers of the transistor M1 is “8”.

### Sixth Embodiment

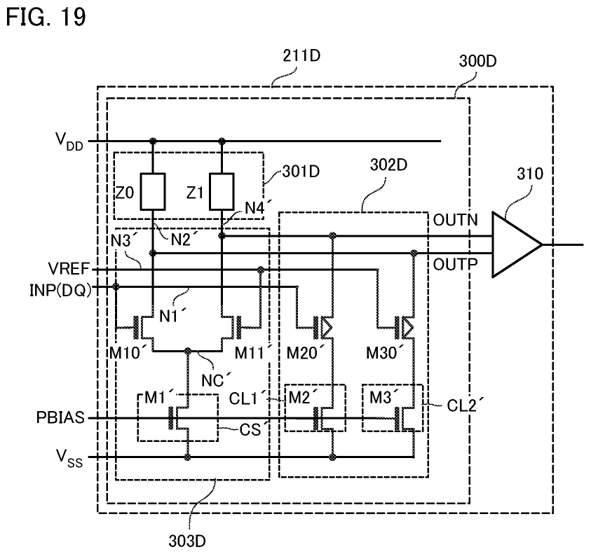

Next, with reference to FIG. 19, a configuration of a semiconductor memory device according to the sixth embodiment is described.

FIG. 19 is a schematic circuit diagram illustrating a configuration of a comparator 211D according to the sixth embodiment. Each of transistors M1′, M2′, M3′, M10′, M11′, M20′, M30′ in the comparator 211D according to the sixth embodiment in FIG. 19 is inversion of PMOS/NMOS of each of the transistors M1, M2, M3, M10, M11, M20, M30 in the comparator 211 according to the first embodiment in FIG. 10A. The transistors M1′, M2′, M3′, M10′, M11′ are constituted by NMOS transistors. The transistors M20′, M30′ are constituted by PMOS transistors.

The comparator 211D includes a first amplifier 300D and the second amplifier 310. The first amplifier 300D includes a differential circuit 303D, a load circuit 301D, and a source follower circuit 302D. The differential circuit 303D includes the transistors M10′, M11′ and the transistor M1′ constituting a current source CS′.

The transistor M10′ has a gate electrode electrically connected to a first node N1′ that inputs the data signal INP, a source electrode electrically connected to a node NC′, and a drain electrode electrically connected to a second node N2′. The transistor M11′ has a gate electrode electrically connected to a third node N3′ that inputs the reference voltage VREF, a source electrode electrically connected to the node NC′, and a drain electrode electrically connected to a fourth node N4′. The transistor M1′ constituting the current source CS' is electrically connected between the ground voltage V_{SS} and the node NC′.

The load circuit 301D is electrically connected between the second node N2′ and the power supply voltage V_{DD} and between the fourth node N4′ and the power supply voltage V_{DD}. Similarly to the load circuit 301 (FIG. 10A), the load circuit 301D includes the first impedance Z0 and the second impedance Z1.

The source follower circuit 302D includes the transistors M20′, M30′, a first current restriction circuit CL1′, and a second current restriction circuit CL2′. The transistor M20′ has a gate electrode electrically connected to the first node N1′, a drain electrode electrically connected to the ground voltage V_{SS}, and a source electrode electrically connected to the fourth node N4′. The transistor M30′ has a gate electrode electrically connected to the third node N3′, a drain electrode electrically connected to the ground voltage V_{SS}, and a source electrode electrically connected to the second node N2′.

The transistor M2′ constituting the first current restriction circuit CL1′ is electrically connected between the drain electrode of the transistor M20′ and the ground voltage V_{SS}, and the transistor M3′ constituting the second current restriction circuit CL2′ is electrically connected between the drain electrode of the transistor M30′ and the ground voltage V_{SS}.

This configuration also allows reducing DCD, allows reducing a jitter, and allows reducing a decrease in the pulse width.

### Seventh Embodiment

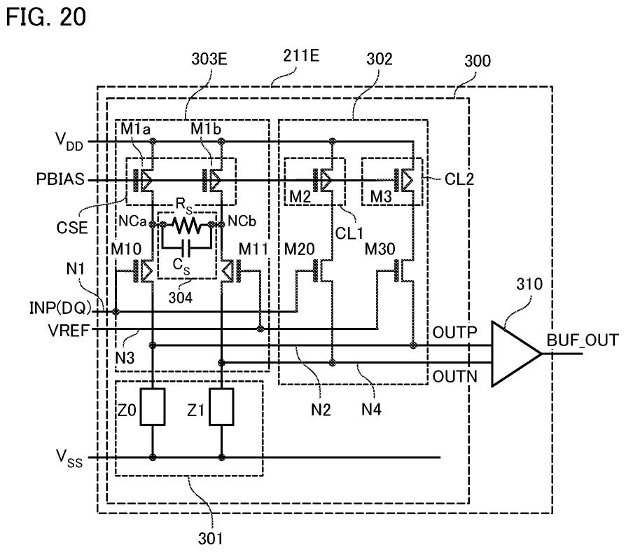

Next, with reference to FIG. 20, a configuration of a semiconductor memory device according to the seventh embodiment is described.

FIG. 20 is a schematic circuit diagram illustrating a configuration of a comparator 211E according to the seventh embodiment. Note that the configuration of the comparator 211E according to the seventh embodiment in FIG. 20 is basically the same as the configuration of the comparator 211 according to the first embodiment in FIG. 10A. However, in the comparator 211E according to the seventh embodiment, a differential circuit 303E is used instead of the differential circuit 303. The differential circuit 303E and the load circuit 301 are differential amplifiers used to correct a frequency characteristic of a transmission line.

The differential circuit 303E is disposed between the power supply voltage V_{DD} and the load circuit 301. The differential circuit 303E includes the transistors M10, M11, a frequency characteristic correction circuit 304, and a current source CSE. The transistors M10, M11 are constituted by PMOS transistors (P type MOS transistors). The transistors M10, M11 constitute a differential pair. The transistor M10 has a gate electrode electrically connected to the first node N1 that inputs the data signal INP, a source electrode electrically connected to the node NCa, and a drain electrode electrically connected to the second node N2. The transistor M11 has a gate electrode electrically connected to the third node N3 that inputs the reference voltage VREF, a source electrode electrically connected to a node NCb, and a drain electrode electrically connected to the fourth node N4.

The frequency characteristic correction circuit 304 is disposed between the node NCa and the node NCb. The frequency characteristic correction circuit 304 includes a resistor element R_{S} and a capacitor C_{S}. The resistor element R_{S} and the capacitor C_{S} are connected in parallel between the node NCa and the node NCb.

The current source CSE is electrically connected between the power supply voltage V_{DD} and the nodes NCa, NCb. The current source CSE is constituted by, for example, transistors M1a, M1b. The transistors M1a, M1b are constituted by PMOS transistors (P type MOS transistors). The transistor M1a has a gate electrode electrically connected to a signal line that inputs the signal PBIAS (bias signal), a source electrode electrically connected to the power supply voltage V_{DD}, and a drain electrode electrically connected to the node NCa. The transistor M1b has a gate electrode electrically connected to a signal line that inputs the signal PBIAS (bias signal), a source electrode electrically connected to the power supply voltage V_{DD}, and a drain electrode electrically connected to the node NCb.

This configuration also allows reducing DCD, allows reducing a jitter, and allows reducing a decrease in the pulse width.

### Other Embodiments

The semiconductor memory devices according to the first embodiment to the seventh embodiment have been described above. However, the above descriptions are merely examples, and the specific configuration, operation, and the like are adjustable as necessary.

For example, in FIG. 18, while the ratios of the widths of the gate regions of the transistors M20, M30 (or the transistors M2, M3, M20, M30) are “1”, the ratio may be “2”. In this case, the drain currents I_{M20}, I_{M30} increase, and the P side signal OUTP and the N side signal OUTN steeply rise. Note that while the number of fingers of the transistors M20, M30 (or the transistors M2, M3, M20, M30) is “1”, the ratio may be “2”. In this case as well, the drain currents I_{M20}, I_{M30} increase and the P side signal OUTP and the N side signal OUTN steeply rise.

Additionally, PMOS/NMOS of the transistors included in the comparators 211A to 211C and 211E according to the second embodiment to the fourth embodiment and the seventh embodiment may be inverted.

### [Others]

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor integrated circuit comprising
an input circuit that includes an amplifier, wherein
the amplifier includes:
a current source electrically connected to a power supply voltage;
a first PMOS transistor having a gate electrically connected to a first node that inputs a data signal, a source electrically connected to the current source, and a drain electrically connected to a second node;
a second PMOS transistor having a gate electrically connected to a third node that inputs a reference signal, a source electrically connected to the current source, and a drain electrically connected to a fourth node;
a load circuit electrically connected between the second node and a ground voltage and between the fourth node and the ground voltage;
a first NMOS transistor having a gate electrically connected to the first node, a drain electrically connected to the power supply voltage, and a source electrically connected to the fourth node;
a second NMOS transistor having a gate electrically connected to the third node, a drain electrically connected to the power supply voltage, and a source electrically connected to the second node;
a first current restriction circuit electrically connected between the drain of the first NMOS transistor and the power supply voltage; and
a second current restriction circuit electrically connected between the drain of the second NMOS transistor and the power supply voltage.

2. The semiconductor integrated circuit according to claim 1, wherein
the load circuit includes:
a first impedance electrically connected between the second node and the ground voltage; and
a second impedance electrically connected between the fourth node and the ground voltage.

3. The semiconductor integrated circuit according to claim 1, wherein
the load circuit includes:
a third NMOS transistor having a drain electrically connected to the second node, a source electrically connected to the ground voltage, and a gate electrically connected to the fifth node;
a fourth NMOS transistor having a drain electrically connected to the fourth node, a source electrically connected to the ground voltage, and a gate electrically connected to the fifth node;
a resistor element electrically connected between the second node and the fifth node; and
a resistor element electrically connected between the fourth node and the fifth node.

4. The semiconductor integrated circuit according to claim 1, wherein
the first current restriction circuit and the second current restriction circuit are PMOS transistors.

5. The semiconductor integrated circuit according to claim 1, wherein
the first current restriction circuit and the second current restriction circuit are resistor elements.

6. The semiconductor integrated circuit according to claim 1, wherein
the amplifier includes:
a first switch transistor electrically connected between the power supply voltage and the current source;
a second switch transistor electrically connected between the power supply voltage and the first NMOS transistor; and
a third switch transistor electrically connected between the power supply voltage and the second NMOS transistor.

7. The semiconductor integrated circuit according to claim 1, wherein
the first NMOS transistor and the second NMOS transistor have gate widths smaller than gate widths of the first PMOS transistor and the second PMOS transistor, and
the first PMOS transistor and the second PMOS transistor have gate widths smaller than a gate width of a transistor of the current source.

8. A semiconductor memory device comprising:
a memory cell array; and
the semiconductor integrated circuit according to claim 1 disposed around the memory cell array.

9. A semiconductor integrated circuit comprising
an input circuit that includes an amplifier, wherein
the amplifier includes:
a current source electrically connected to a ground voltage;
a first NMOS transistor having a gate electrically connected to a first node that inputs a data signal, a source electrically connected to the current source, and a drain electrically connected to a second node;
a second NMOS transistor having a gate electrically connected to a third node that inputs a reference signal, a source electrically connected to the current source, and a drain electrically connected to a fourth node;
a load circuit electrically connected between the second node and a power supply voltage and between the fourth node and the power supply voltage;
a first PMOS transistor having a gate electrically connected to the first node, a drain electrically connected to the ground voltage, and a source electrically connected to the fourth node;
a second PMOS transistor having a gate electrically connected to the third node, a drain electrically connected to the ground voltage, and a source electrically connected to the second node;
a first current restriction circuit electrically connected between the drain of the first PMOS transistor and the ground voltage; and
a second current restriction circuit electrically connected between the drain of the second PMOS transistor and the ground voltage.

10. A semiconductor memory device comprising:
a memory cell array; and
the semiconductor integrated circuit according to claim 9 disposed around the memory cell array.
